(19) United States
(12) Patent Application Publication
(10) Pub. No.: US 2024/0016061 A1
(43) Pub. Date: Jan. 11, 2024

(54) PIEZOELECTRIC ELEMENT, METHOD OF MANUFACTURING THE SAME, TOUCHPAD INCLUDING THE SAME, AND METHOD OF OPERATING THE SAME

(71) Applicant: INDUSTRY-ACADEMIC COOPERATION FOUNDATION, DANKOOK UNIVERSITY, Yongin-si (KR)

(72) Inventors: Ji-Hyeon Song, Yongin-si (KR); Yujun Song, Yongin-si (KR)

(73) Assignee: INDUSTRY-ACADEMIC COOPERATION FOUNDATION, DANKOOK UNIVERSITY, Yongin-si (KR)

(21) Appl. No.: 18/220,295

(22) Filed: Jul. 11, 2023

(30) Foreign Application Priority Data
Jul. 11, 2022 (KR) 10-2022-0085054
Jul. 11, 2022 (KR) 10-2022-0085058

(51) Int. Cl. H10N 30/30; H10N 30/045; H10N 30/072; H10N 30/088; G06F 3/041

(52) U.S. Cl. CPC H10N 30/30; H10N 30/045; H10N 30/072; H10N 30/088; G06F 3/0414; G06F 3/04164

(57) ABSTRACT

Disclosed herein are a piezoelectric element, a method of manufacturing the piezoelectric element, a touchpad including the piezoelectric element, and a method of operating the touchpad, wherein the piezoelectric element has a shape of an N-hedron and includes N polygonal unit piezoelectric films forming N faces of the N-hedron, and the touchpad includes: a first piezoelectric element having a shape of an N-hedron; a pad body having a first installation groove detachably supporting the first piezoelectric element; and a signal processer receiving and processing a first signal generated by the first piezoelectric element in response to a first external force, wherein N unit signals are generated by N unit piezoelectric films forming N faces of the first piezoelectric element in response to one external force.

### FIELD

The present invention relates to a piezoelectric element, a method of manufacturing the piezoelectric element, a touchpad including the piezoelectric element, and a method of operating the touchpad. More particularly, the present invention relates to a piezoelectric element that has a polyhedral structure including multiple unit piezoelectric films to generate multiple electrical signals in response to external mechanical pressure, a touchpad including the piezoelectric element, and a method of operating the touchpad.

### BACKGROUND

A piezoelectric element is a device that has a piezoelectric effect, that is, the ability to output voltage as an electrical signal in response to applied mechanical pressure and mechanically deforms in response to applied voltage.

Piezoelectric elements subjected to electrical poling are used in a variety of applications including sensors, actuators, transducers, and energy harvesters, since they generate a potential difference in response to external force and deform in response to applied voltage.

Such a piezoelectric element generally includes a piezoelectric thin film formed of a piezoelectric material and first and second electrodes with the piezoelectric thin film interposed therebetween. That is, the piezoelectric element has a structure in which the first electrode, the piezoelectric thin film, and the second electrode are stacked in sequence.

When pressure (force) is applied to the piezoelectric element in a certain direction, opposite charges are induced on the first electrode and the second electrode, respectively, in response to displacement of the piezoelectric thin film due to resistance (stress) against the applied pressure, causing generation of voltage between the first electrode and the second electrode, which is called a direct piezoelectric effect. Conversely, voltage applied between the first electrode and the second electrode causes mechanical displacement of the piezoelectric thin film, which is called a reverse piezoelectric effect.

Basically, the piezoelectric thin film may have basic vibration modes depending on the poling direction thereof and the direction of force applied thereto. That is, there may be three basic vibration modes, referred to as 31, 32, and 33 modes, where the first digit of each number represents a poling direction and the second digit represents a direction of mechanical displacement. In the 31 and 32 modes, the poling direction and the displacement direction of the piezoelectric thin film are perpendicular to each other and, in the 33 mode, the poling direction and the displacement direction of the piezoelectric thin film are identical to each other. As such, the piezoelectric thin film can generate signals of different values depending on the poling direction thereof and the direction of force applied thereto in each of the basic vibration modes 31, 32, 33.

A conventional piezoelectric element is a single piezoelectric element and generates only one signal corresponding to unidirectional stress against external force. If there is a piezoelectric element capable of generating multiple output signals in response to external force, the piezoelectric element can improve reliability and utilization of sensors, actuators, transducers, and energy harvesters employing the piezoelectric element. In particular, if there is a piezoelectric element capable of generating output signals in various magnitudes and quantities in response to applied external force, the piezoelectric element can significantly improve a security level of security touchpads employing the piezoelectric element, such as door locks.

### RELATED LITERATURE

### Patent Document

(Patent Document 1) Korean Patent Laid-open Publication No. 2022-0007694 (published on Jan. 18, 2022)

### SUMMARY

Embodiments of the present invention are conceived to solve such problems in the art and provide a piezoelectric element capable of simultaneously generating multiple different electrical signals in response to external mechanical pressure, a method of manufacturing the piezoelectric element, a touchpad including the piezoelectric element, and a method of operating the touchpad.

It will be understood that objects of the present invention are not limited to the above. The above and other objects of the present invention will become apparent to those skilled in the art from the detailed description of the following embodiments in conjunction with the accompanying drawings.

In accordance with one aspect of the present invention, a piezoelectric element has a shape of an N-hedron and includes N unit piezoelectric films having a shape of a polygon and forming N faces of the N-hedron.

Accordingly, N unit signals may be generated by the N unit piezoelectric films in response to one external force applied to one face of the N-hedron.

Each of the N unit signals may depend on stress generated in a corresponding one of the N unit piezoelectric films in response to the one external force and a poling direction of a corresponding one of the N unit piezoelectric films.

The N unit piezoelectric films may include: a first unit piezoelectric film in which a first stress is generated against the one external force; and a second unit piezoelectric film in which a second stress is generated against the one external force.

The first unit piezoelectric film may have a first poling direction with respect to the one external force and the second unit piezoelectric film may have a second poling direction different from the first poling direction with respect to the one external force.

The first unit piezoelectric film may generate a first unit signal corresponding to the first stress and the first poling direction, and the second unit piezoelectric film may generate a second unit signal corresponding to the second stress and the second poling direction.

The N unit piezoelectric films may be formed by cutting a mother piezoelectric film sheet having a predetermined poling direction.

The N-hedron may be a regular N-hedron and the polygon may be a regular polygon.

In accordance with another aspect of the present invention, a piezoelectric element has a shape of an N-hedron and includes one or more unit piezoelectric films forming one or more faces of the N-hedron, respectively, wherein one or more unit signals are generated by the one or more unit piezoelectric films, respectively, in response to one external force applied to one face of the N-hedron.

In accordance with a further aspect of the present invention, a method of manufacturing a piezoelectric element includes the steps of: fabricating a mother piezoelectric film sheet subjected to poling to have a predetermined poling direction; forming a piezoelectric film net for an N-hedron by cutting the mother piezoelectric film sheet; and forming an N-hedron including N unit piezoelectric films as N faces thereof by processing the piezoelectric film net.

The step of forming a piezoelectric film net may include: setting the type of N-hedron; and setting a pattern of the piezoelectric film net for a set N-hedron.

In accordance with yet another aspect of the present invention, a touchpad includes: a first piezoelectric element having a shape of an N-hedron; a pad body having a first installation groove detachably supporting the first piezoelectric element; and a signal processer receiving and processing a first signal generated by the first piezoelectric element in response to a first external force.

The touchpad may further include: a second piezoelectric element having a shape of an N-hedron.

The pad body may further have a second installation groove detachably supporting the second piezoelectric element, and the signal processer may further receive and process a second signal generated by the second piezoelectric element in response to a second external force.

The first signal generated by the first piezoelectric element may vary depending on which face of the N-hedron is subjected to the first external force.

The first signal generated by the first piezoelectric element may vary depending on a magnitude of the first external force.

The first piezoelectric element may include N first unit identification numbers corresponding to N faces thereof and the second piezoelectric element may include N second unit identification numbers corresponding to N faces thereof.

The signal processer may determine: whether an input order of the first external force and the second external force matches a preset reference input order; whether, among the N first unit identification numbers, a first unit identification number subjected to the first external force matches a preset first reference unit identification number; whether, among the N second unit identification numbers, a second unit identification number subjected to the second external force matches a preset second reference unit identification number; whether a magnitude of the first signal matches a magnitude of a preset first reference signal; and whether a magnitude of the second signal matches a magnitude of a preset second reference signal.

The first piezoelectric element may include N unit piezoelectric films forming N faces of the N-hedron and N first unit signals may be generated by the N unit piezoelectric films in response to the first external force applied to one of the N unit piezoelectric films, wherein the first signal may be one of the N first unit signals or a sum of the N first unit signals.

Each of the N unit piezoelectric films may include a first electrode and a second electrode, and the first piezoelectric element may include at least two integrated electrode units formed at one side of an outer surface thereof facing the first installation groove and electrically connected to the N first electrodes and the N second electrodes.

The pad body may include an electrode connection portion formed on each inner surface of the first installation groove, excluding an opening of the first installation groove, to be electrically connected to the integrated electrode units, regardless of a position of the first piezoelectric element on the first installation groove.

In accordance with yet another aspect of the present invention, a method of operating a touchpad includes the steps of: setting a position of an N-hedral piezoelectric element on an installation groove of a pad body such that a predetermined face of the piezoelectric element is exposed externally; and pressing the piezoelectric element in accordance with preset reference touch information.

In accordance with yet another aspect of the present invention, a touchpad includes a first piezoelectric element having a shape of an N-hedron, wherein the first piezoelectric element includes one or more unit piezoelectric films forming one or more faces of the N-hedron, respectively; one or more first unit signals are generated by the one or more unit piezoelectric films, respectively, in response to a first external force applied to one face of the N-hedron; and a first signal is one of the one or more first unit signals or a sum of the one or more first unit signals.

According to the present invention, multiple different electrical signals can be simultaneously generated in response to externally applied mechanical pressure using a polyhedral piezoelectric element including multiple unit piezoelectric films as faces thereof.

According to the present invention, by varying a net pattern for a polyhedral piezoelectric element, a signal generated by each face of the piezoelectric element can be varied in type or size.

As such, the polyhedral piezoelectric element according to the present invention can have improved reliability and utilization due to the ability to generate multiple signals in response to one external force.

In addition, the polyhedral piezoelectric element according to the present invention can have further improved reliability and utilization in piezoelectric products, such as sensors, actuators, transducers, and energy harvesters, due to the ability to output signals of various sizes and quantities in response to external force.

The touchpad including an N-hedral piezoelectric element according to the present invention can have improved operational reliability and security level due to the ability to output various signals depending on which face of the N-hedron is subjected to external force.

The touchpad including the N-hedral piezoelectric element according to the present invention can have further improved operational reliability and security level due to the ability to output various signals depending on the magnitude of applied external force.

According to the present invention, a signal generated by each face of the N-hedral piezoelectric element can be varied by varying a net pattern for the piezoelectric element, thereby facilitating manufacture of the piezoelectric element and the touchpad.

The touchpad including the N-hedral piezoelectric element according to the present invention can have improved utilization due to the ability to set and output signals of various sizes and quantities in response to external force.

It will be understood that advantageous effects of the present invention are not limited to the above ones, and include any advantageous effects conceivable from the features disclosed in the detailed description of the present invention or the appended claims.

### DRAWINGS

The above and other aspects, features, and advantages of the present invention will become apparent from the detailed description of the following embodiments in conjunction with the accompanying drawings:

FIG. 1 is an exemplary view of a piezoelectric element according to one embodiment of the present invention;

FIG. 2 is an exemplary partial sectional view of a unit piezoelectric film according to one embodiment of the present invention;

FIG. 3 is an exemplary view of a hexahedral piezoelectric element according to one embodiment of the present invention;

FIG. 4 is a sectional view illustrating operation of the hexahedral piezoelectric element of FIG. 3;

FIG. 5 illustrates various unit signals depending on a poling direction of a second unit piezoelectric film joined edge-to-edge with a first unit piezoelectric film directly subjected to external force in a hexahedral piezoelectric element according to one embodiment of the present invention;

FIG. 6 is an exemplary view of a piezoelectric element according to another embodiment of the present invention;

FIG. 7 is a flow diagram of a piezoelectric element manufacturing method according to one embodiment of the present invention;

FIG. 8 illustrates a mother piezoelectric film sheet fabrication step of FIG. 8;

FIG. 9 illustrates a net formation step of FIG. 8;

FIG. 10 illustrates an N-hedron formation step of FIG. 8;

FIG. 11 illustrates various patterns of a net for a hexahedral piezoelectric element according to one embodiment of the present invention;

FIG. 12 and FIG. 13 are exemplary views illustrating variation in poling direction of each unit piezoelectric film depending on the net pattern for a hexahedral piezoelectric element according to one embodiment of the present invention;

FIG. 14 is an exemplary diagram of a touchpad according to one embodiment of the present invention;

FIG. 15 is an exemplary partial sectional view of a unit piezoelectric film according to another embodiment of the present invention;

FIG. 16 is an exemplary view illustrating electrical connection between a piezoelectric element and a pad body according to another embodiment of the present invention; and

FIG. 17 is a flow diagram of a touchpad operation method according to one embodiment of the present invention.

### DETAILED DESCRIPTION

Hereinafter, exemplary embodiments of the present invention will be described with reference to the accompanying drawings. In description of the embodiments, the same components will be denoted by the same terms and the same reference numerals and repeated description thereof will be omitted.

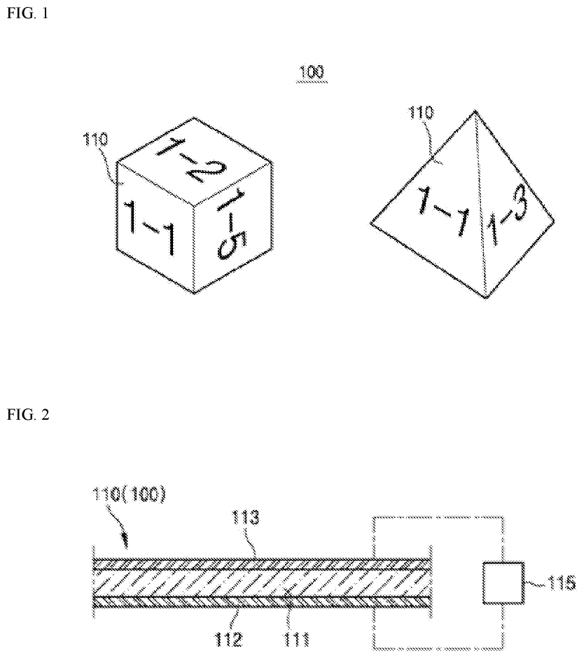

FIG. 1 is an exemplary view of a piezoelectric element according to one embodiment of the present invention and FIG. 2 is an exemplary partial sectional view of a unit piezoelectric film according to one embodiment of the present invention.

Referring to FIG. 1, a piezoelectric element 100 according to one embodiment of the invention may have a shape of a polyhedron having N faces, that is, an N-hedron.

Thus, the piezoelectric element 100 may include N polygonal unit piezoelectric films 110 forming N faces of the N-hedron, respectively.

Alternatively, the piezoelectric element 100 may have a shape of an N-hedron and may include one or more unit piezoelectric films forming one or more faces of the N-hedron, respectively, wherein one or more unit signals may be generated by the one or more unit piezoelectric films, respectively, in response to external force applied to one face of the N-hedron.

That is, all the N faces may be formed of a respective unit piezoelectric film 110, or one or more of the N faces may be formed of a respective unit piezoelectric film 110.

When one or more faces of the N-hedron are formed of a respective unit piezoelectric film, only the one or more faces may generate a respective unit signal and a signal from the piezoelectric element may vary in type (magnitude) depending on how many unit piezoelectric films the piezoelectric element includes and which face of the N-hedron is formed of the unit piezoelectric film.

When each face of the N-hedron is formed of a respective unit piezoelectric film, N unit signals may be generated by the N faces in response to one external force, wherein each unit signal may vary depending on a poling direction of a corresponding unit piezoelectric film and a (total) signal from the piezoelectric element may be determined by combining the N unit signals.

On the other hand, when only some (at least one) of the N faces is formed of a respective unit piezoelectric film, a respective unit signal may be generated only by the some faces, wherein each unit signal may vary depending on a poling direction of a corresponding unit piezoelectric film and a new signal may be produced by combining the unit signals.

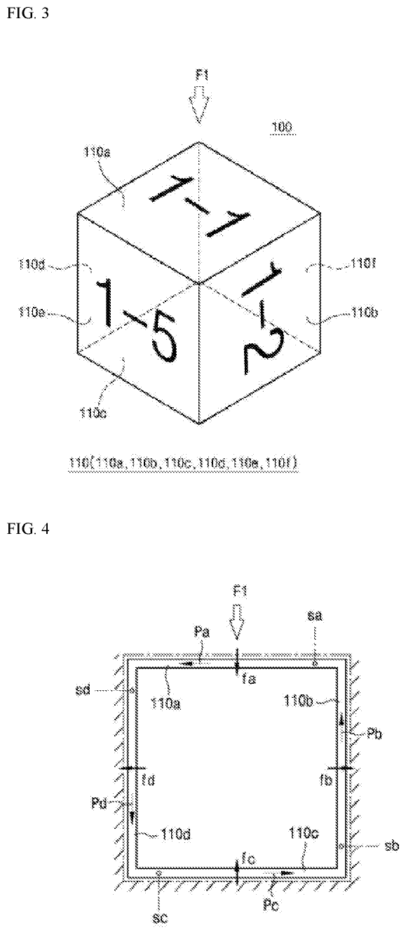

For example, referring to FIG. 3, only a 1-1 face may be formed of a unit piezoelectric film with 1-2 to 1-6 faces not formed of a unit piezoelectric film. Here, the unit piezoelectric film forming the 1-1 face may be poled in a transverse direction, a longitudinal direction, a height direction, or another different direction. When external force is perpendicularly applied to the 1-1 face, as shown in FIG. 3, a unit signal generated by the 1-1 face varies depending on the poling direction of the unit piezoelectric film forming the 1-1 face.

Alternatively, two or more faces, including the 1-1 face and another face (such as a 1-3 face or a 1-5 face) may be formed of a unit piezoelectric film, wherein each unit piezoelectric film may have a different poling direction and a new signal may be produced by combining unit signals generated by the two or more faces.

As will be described below, the unit piezoelectric film may have a predetermined poling direction through a process in which a mother piezoelectric film sheet subjected to poling is fabricated, followed by formation of a net for an N-hedron by cutting the mother piezoelectric film sheet, and then the net is folded into an N-hedral piezoelectric element. Here, only a portion of the mother piezoelectric film sheet may be subjected to poling, or only a required portion of a net for an N-hedron drawn in advance on the mother piezoelectric film sheet may be subjected to poling.

Alternatively, different unit piezoelectric films poled in one direction may be attached only to a required portion of a net for an N-hedron drawn on a base film (not shown).

In the following, embodiments of N polygonal unit piezoelectric films forming N faces of an N-hedron will be described in detail.

Referring to FIG. 1, a tetrahedral piezoelectric element 100 may include four triangular unit piezoelectric films 110, and a hexahedral piezoelectric element 100 may include six rectangular unit piezoelectric films 110.

In some embodiments, the piezoelectric element 100 may have a shape of a regular N-hedron and thus each unit piezoelectric film 110 may have a shape of a regular polygon.

Referring to FIG. 2, the unit piezoelectric film 110 may be provided in the form of a thin membrane or film and may include a piezoelectric material layer 111, a first electrode 112 disposed on one surface of the piezoelectric material layer 111, and a second electrode 113 disposed on the other surface of the piezoelectric material layer 111 and having an opposite polarity to the first electrode 112.

That is, the unit piezoelectric film 110 may be fabricated by sequentially stacking the first electrode 112, the piezoelectric material layer 111, and the second electrode 113. Although the unit piezoelectric film 110 is shown as including a single piezoelectric material layer 111, it should be understood that the present invention is not limited thereto and the unit piezoelectric film 110 may include a stack of multiple piezoelectric material layers 111. The piezoelectric material layer 111 may include PVDF, PZT, BaTiO₃, LiNbO₃, quartz, and the like.

When external pressure is applied to the unit piezoelectric film 110 in a certain direction, a positive (+) charge is induced on the first electrode 112 and a negative (−) charge is induced on the second electrode 113 in response to stress (resistance force) generated in the unit piezoelectric film 110, causing generation of voltage between the first electrode 112 and the second electrode 113.

The unit piezoelectric film 110 may be electrically connected to a unit signal measurement unit 115. The unit signal measurement unit 115 may measure an electrical signal as voltage generated between the first electrode 112 and the second electrode 113. That is, the unit signal measurement unit 115 may measure a unit signal generated by the unit piezoelectric film 110. There may be provided N unit signal measurement units 115 corresponding to N unit piezoelectric films 110, such that the N-hedral piezoelectric element 100 may simultaneously generate N unit signals in response to one external force F.

The unit signal measurement unit 115 may be electrically connected to a signal processer. That is, N unit signals measured by N unit signal measurement units 115 may be transmitted to the signal processer, which, in turn, may output a single summed signal through summation of the N unit signals. The signal processer may individually output N unit signals generated by the N-hedral piezoelectric element 100, may output only one of the N unit signals, or may output a summed signal of the N unit signals.

Referring to FIG. 3, a hexahedral piezoelectric element 100 may include six unit piezoelectric films 110a, 110b, 110c, 110d, 110e, 110f.

When external force F1 is applied to one face of the hexahedral piezoelectric element 100, that is, one unit piezoelectric film 110a, the hexahedral piezoelectric element 100 may generate six unit signals.

Here, each of the six unit signals may depend on stress generated in a corresponding one of the six unit piezoelectric films 110a, 110b, 110c, 110d, 110e, 110f in response to one external force F1 and a poling direction of a corresponding one of the six unit piezoelectric films 110a, 110b, 110c, 110d, 110e, 110f.

Referring further to FIG. 4, the piezoelectric element 100 may include a first unit piezoelectric film 110a and a second unit piezoelectric film 110b and external force F1 may be applied perpendicular to a plane of the first unit piezoelectric film 110a.

The first unit piezoelectric film 110a may be disposed perpendicular to the external force F1. The first unit piezoelectric film 110a may have a first poling direction Pa with respect to the external force F1 and a first stress fa may be generated in the first unit piezoelectric film 110a against the external force F1. For example, the first stress fa may be compressive or tensile stress. Accordingly, the first unit piezoelectric film 110a having the first poling direction Pa may generate a first unit signal sa corresponding to the first stress fa.

For a hexahedral piezoelectric element 100, the first unit piezoelectric film 110a subjected to the external force F1 may generate the first unit signal sa corresponding to the first stress fa, regardless of the first poling direction Pa thereof.

The second unit piezoelectric film 110b may be joined edge-to-edge with the first unit piezoelectric film 110a to be disposed at a predetermined angle of inclination with respect to the external force F1. The second unit piezoelectric film 110b may have a second poling direction Pb with respect to the external force F1 and a second stress fb may be generated in the second unit piezoelectric film 110b against the external force F1. Here, the second poling direction Pb may be different from the first poling direction Pa, and the magnitude of the second stress fb may be different from that of the first stress fa. For example, the second stress fb may be bending stress. Accordingly, the second unit piezoelectric film 110b having the second poling direction Pb may generate a second unit signal sb corresponding to the second stress fb.

The piezoelectric element 100 may further include a third unit piezoelectric film 110c and a fourth unit piezoelectric film 110d.

The third unit piezoelectric film 110c may be joined edge-to-edge with the second unit piezoelectric film 110b to be disposed perpendicular to the external force F1. The third unit piezoelectric film 110c may have a third poling direction Pc with respect to the external force F1 and a third stress fc may be generated in the third unit piezoelectric film 110c against the external force F1. Here, the third poling direction Pc may be different from the first poling direction Pa and the second poling direction Pb, and the magnitude of the third stress fc may be different from those of the first stress fa and the second stress fb. For example, the third stress fc may be compressive or tensile stress. Accordingly, the third unit piezoelectric film 110c having the third poling direction Pc may generate a third unit signal sc corresponding to the third stress fc.

For a hexahedral piezoelectric element 100, the third unit signal sc may be identical to the first unit signal sa. That is, the third unit piezoelectric film 110c disposed opposite the first unit piezoelectric film 110a subjected to the external force F1 may generate the same unit signal as the first unit piezoelectric film 110c, regardless of the third poling direction Pc thereof.

The fourth unit piezoelectric film 110d may be joined edge-to-edge with the first unit piezoelectric film 110a to be disposed at a predetermined angle of inclination with respect to the external force F1. The fourth unit piezoelectric film 110d may have a fourth poling direction Pd with respect to the external force F1 and a fourth stress fd may be generated in the fourth unit piezoelectric film 110d against the external force F1. Here, the fourth poling direction Pd may be different from the first poling direction Pa, the second poling direction Pb, and the third poling direction Pc, and the magnitude of the fourth stress fd may be different from those of the first stress fa, the second stress fb, and the third stress fc. For example, the fourth stress FD may be bending stress. Accordingly, the fourth unit piezoelectric film 110d having the fourth poling direction Pd may generate a fourth unit signal sd corresponding to the fourth stress fd.

Although not shown, the hexahedral piezoelectric element 100 may further include a fifth unit piezoelectric film and a sixth unit piezoelectric film.

The fifth unit piezoelectric film may have a fifth poling direction with respect to the external force F1 and a fifth stress may be generated in the fifth unit piezoelectric film against the external force F1. Accordingly, the fifth unit piezoelectric film may generate a fifth unit signal corresponding to the fifth stress. The sixth unit piezoelectric film may have a sixth poling direction with respect to the external force F1 and a sixth stress may be generated in the sixth unit piezoelectric film against the external force F1. Accordingly, the sixth unit piezoelectric film may generate a sixth unit signal corresponding to the sixth stress.

Stress generated in each unit piezoelectric film 110 may vary in magnitude depending on the type of N-hedron. In addition, stress generated in each unit piezoelectric film 110 may vary in magnitude depending on the type of material, thickness, width, length, elastic modulus, specific dielectric constant, and static displacement rate of the piezoelectric material layer 111 of a corresponding unit piezoelectric film.

Each unit piezoelectric film 110 may have basic vibration modes in three independent directions corresponding to the poling direction and stress direction thereof. Accordingly, a respective unit signal generated by each unit piezoelectric film may vary depending on in which direction a corresponding unit piezoelectric film is poled through a piezoelectric element manufacturing process.

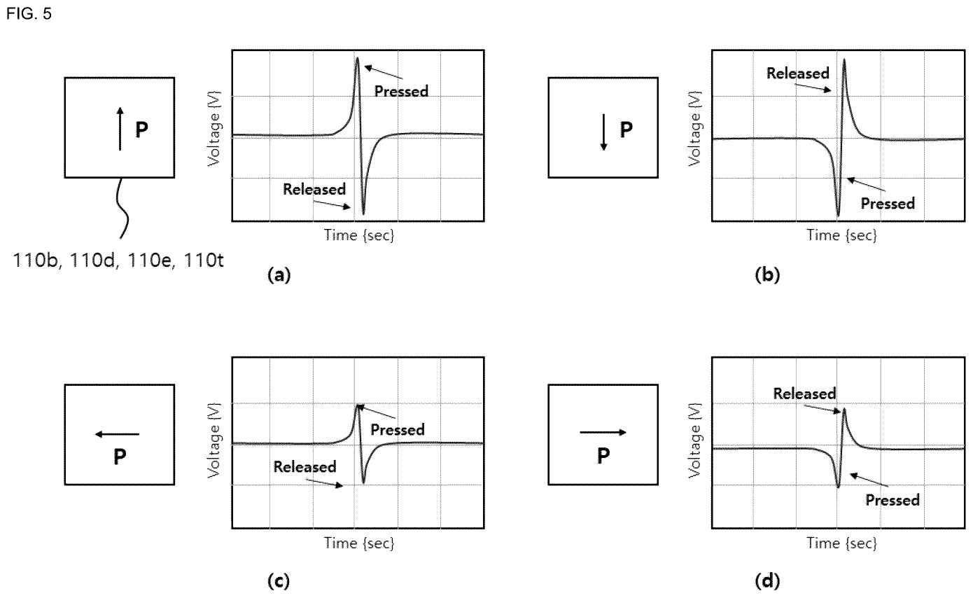

FIG. 5 illustrates various unit signals from the second unit piezoelectric film joined edge-to-edge with the first unit piezoelectric film subjected to external force depending on the poling direction of the second unit piezoelectric film in a hexahedral piezoelectric element according to one embodiment of the present invention.

As in this embodiment, for a hexahedral piezoelectric element 100, the second unit piezoelectric film 110b joined edge-to-edge with the first unit piezoelectric film 110a subjected to the external force F1 may generate different unit signals depending on the poling direction P thereof.

That is, referring to FIG. 5, each unit piezoelectric film 110 may have a poling direction P oriented upward (FIG. 5(a)), downward (FIG. 5(b)), leftward (FIG. 5(c)), or rightward (FIG. 5(d)), whereby the multiple unit piezoelectric films 110 may generate multiple different unit signals, respectively, depending on the poling directions P thereof.

Although FIG. 5 shows that the poling direction P of the unit piezoelectric film 110 is oriented upward, downward, leftward, or rightward, it should be understood that each unit piezoelectric film 110 may have a poling direction P oriented at an oblique angle.

That is, each unit piezoelectric film 110 may have a poling direction P oriented right upward, left downward, left upward, or right downward. Accordingly, the multiple unit piezoelectric films 110 may generate multiple different unit signals, respectively, depending on the obliquely oriented poling directions P thereof.

When each unit piezoelectric film 110 has an obliquely oriented poling direction P, the poling directions P of the respective unit piezoelectric films 110 may have different slopes.

As described above, for a hexahedral piezoelectric element 100, the first unit piezoelectric film 110a subjected to external force F1 and the third unit piezoelectric film 110c disposed opposite the first unit piezoelectric film 110a may generate the same unit signal regardless of the poling directions P thereof, and the other unit piezoelectric films 110b, 110d, 110e, 110f joined edge-to-edge with the first unit piezoelectric film 110a and the third unit piezoelectric film 110c and forming four side surfaces of the hexahedral piezoelectric element 100 may generate different unit signals depending on the poling directions P thereof.

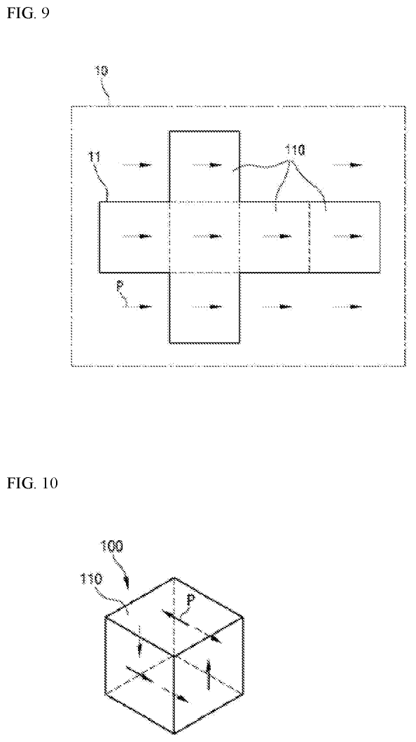

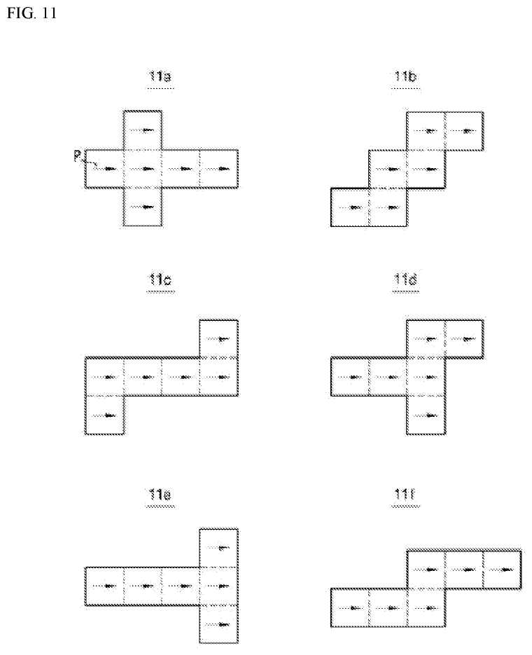

N unit piezoelectric films 110 may be poled in respective predetermined directions through a piezoelectric element manufacturing process. For example, by fabricating a mother piezoelectric film sheet 10 having a predetermined poling direction P (see FIG. 8), cutting the fabricated mother piezoelectric film 10 sheet into a piezoelectric film net 11 for an N-hedron (see FIG. 9), and processing the formed piezoelectric film net 11 into the N-hedron, N unit piezoelectric films 110 forming N faces of the N-hedron can have different poling directions P (see FIG. 10).

Here, the piezoelectric film net 11 may be formed in various patterns. By varying the pattern of the piezoelectric film net 11, the N unit piezoelectric films 110 forming the N faces of the N-hedron can be varied in poling direction.

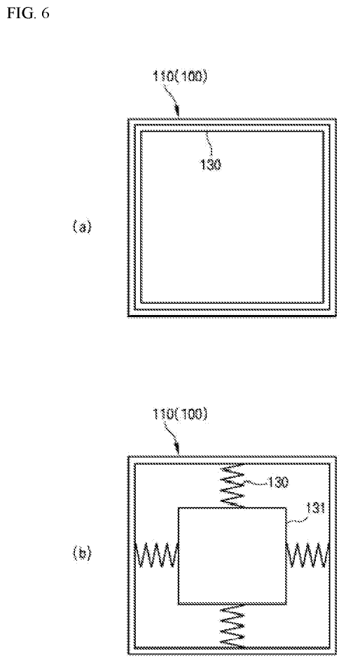

FIG. 6 is an exemplary view of a piezoelectric element according to another embodiment of the present invention.

Referring to FIG. 6, a piezoelectric element 100 according to this embodiment may further include a piezoelectric film support member 130.

The piezoelectric film support member 130 may be disposed inside the piezoelectric element 100, that is, on an inner surface of a unit piezoelectric film 110, to support the unit piezoelectric film 110.

The piezoelectric film support member 130 may allow displacement of the unit piezoelectric film 110 due to stress generated in response to external force and may allow restoration of the unit piezoelectric film 110 to an original position upon removal of the external force from the unit piezoelectric film 110.

The piezoelectric film support member 130 may be formed of an elastic material.

For example, the piezoelectric film support member 130 may be provided in the form of a substrate bonded to the inner surface of the unit piezoelectric film 110, as shown in FIG. 6(a). By way of another example, the piezoelectric film support member 130 may be provided to connect the inner surface of the unit piezoelectric film 110 to a base portion 131 disposed inside the piezoelectric element 100, as shown in FIG. 6(b). Here, the piezoelectric film support member 130 may connect inner surfaces of a pair of opposing unit piezoelectric films 110 to each other with the base portion 131 excluded from the piezoelectric element 100.

When a piezoelectric material layer 111 of the unit piezoelectric film 110 is formed of a brittle material, the piezoelectric material layer 111 can be easily broken upon deformation by external force. The piezoelectric film support member 130, such as an elastic substrate, imparts toughness to the piezoelectric material layer 111, thereby allowing the piezoelectric material layer 111 to be deformed immediately and effectively without any cracks or damage in response to applied external force.

Next, a piezoelectric element manufacturing method according to one embodiment of the present invention will be described.

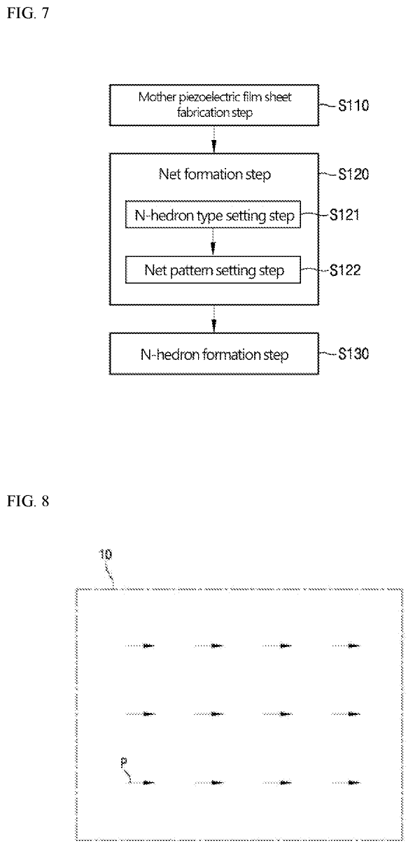

FIG. 7 is a flow diagram of a piezoelectric element manufacturing method according to one embodiment of the present invention, FIG. 8 illustrates a mother piezoelectric film sheet fabrication step of FIG. 7, FIG. 9 illustrates a net formation step of FIG. 7, and FIG. 10 illustrates an N-hedron formation step of FIG. 7.

A piezoelectric element manufacturing method according to this embodiment may include a mother piezoelectric film sheet fabrication step S110, a net formation step S120, and an N-hedron formation step S130.

Referring to FIG. 7 and FIG. 8, the mother piezoelectric film sheet fabrication step S110 may be a step in which a mother piezoelectric film sheet subjected to poling to have a predetermined poling direction P is fabricated.

The mother piezoelectric film sheet may be fabricated in the form of a thin membrane or film including a first electrode 112, a piezoelectric material layer 111, and a second electrode 113 stacked in sequence (see FIG. 2).

The mother piezoelectric film sheet 10 thus fabricated may have uniformly oriented poling directions P.

Referring to FIG. 7 and FIG. 9, the net formation step S120 may be a step in which a piezoelectric film net 11 for an N-hedron is formed by cutting the fabricated mother piezoelectric film sheet 10.

The net formation step S120 may include an N-hedron type setting step S121 and a net pattern setting step S122.

The N-hedron type setting step S121 may be a step in which the type of N-hedron is set.

That is, the type of N-hedron, such as a tetrahedron, a hexahedron, an octahedron, a dodecahedron, and an icosahedron, may be set according to the intended use of the piezoelectric element 100.

The net pattern setting step S122 may be a step in which a pattern of the piezoelectric film net 11 for the set N-hedron is set.

After setting of the type of N-hedron and setting of the pattern of the piezoelectric film net 11 are completed, the piezoelectric film net 11 is separated from the mother piezoelectric film sheet 10 by cutting along cutting lines corresponding to the net pattern drawn on the mother piezoelectric film sheet 10.

Here, the piezoelectric film net 11 is separated from the mother piezoelectric film sheet 10 such that neighboring unit piezoelectric films 110 of the piezoelectric film net 11 share vertices. That is, multiple unit piezoelectric films 110 forming the piezoelectric film net 11 may be connected to each other via the vertices.

Referring to FIG. 7, FIG. 9, and FIG. 10, the N-hedron formation step S130 may be a step in which the piezoelectric film net 11 is processed into an N-hedron including N unit piezoelectric films 110 as N faces thereof.

That is, an N-hedral piezoelectric element 100 having N faces each formed of a unit piezoelectric film 110 is manufactured by processing the piezoelectric film net 11.

In the N-hedral piezoelectric element 100 thus manufactured, neighboring unit piezoelectric films 110 sharing an edge may be connected to each other via common vertices. Accordingly, stress can be effectively generated in the multiple unit piezoelectric films 110 in response to applied external force.

FIG. 11 illustrates various patterns of a net for a hexahedral piezoelectric element.

Referring to FIG. 11, for a hexahedral piezoelectric element, there may be provided various patterns of piezoelectric film nets 11a to 11f. When the type of N-hedron is set as a hexahedron in step S121, one of various patterns of piezoelectric film nets 11a to 11f for the hexahedron may be selected.

Depending on the pattern of the piezoelectric film net 11, the poling direction P of each unit piezoelectric film 110 constituting an N-hedral piezoelectric element 100 may vary, which, in turn, may cause variation in the unit signal generated upon occurrence of stress in a corresponding unit piezoelectric film 110.

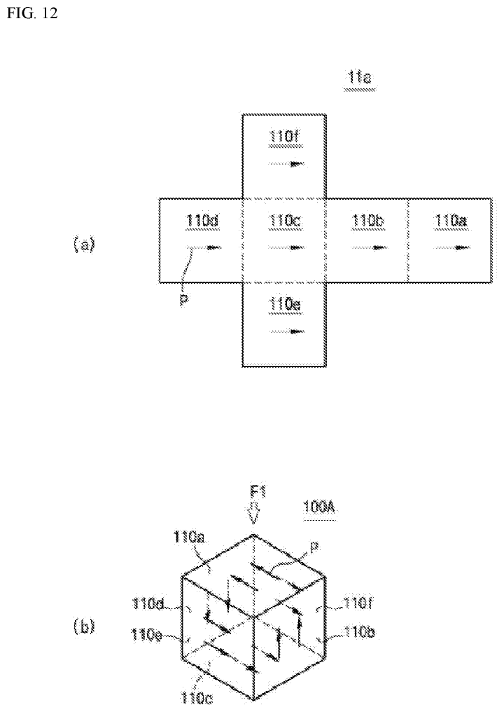

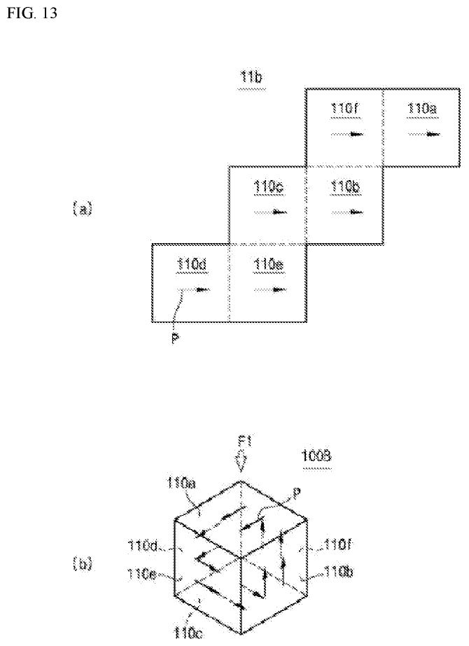

FIG. 12 and FIG. 13 are exemplary views illustrating variation in poling direction of each unit piezoelectric film depending on the net pattern for a hexahedral piezoelectric element according to one embodiment of the present invention.

A first piezoelectric element 100A shown in FIG. 12 may be manufactured in a hexahedral shape by processing a first piezoelectric film net 11a, and a second piezoelectric element 100B shown in FIG. 13 may be manufactured in a hexahedral shape by processing a second piezoelectric film net 11b different from the first piezoelectric film net 11a.

The first piezoelectric element 100A and the second piezoelectric element 100B thus manufactured may differ from each other in terms of poling direction P of each unit piezoelectric film 110a to 110f. That is, since the first piezoelectric film net 11a for the first piezoelectric element 100A has a different pattern than the second piezoelectric film net 11b for the second piezoelectric element 100B, poling directions P of unit piezoelectric films of the first piezoelectric element 100A may be different from those of unit piezoelectric films of the second piezoelectric element 100B. As a result, in response to the same external force F1, the first piezoelectric element 100A and the second piezoelectric element 100B may generate multiple different unit signals from each other.

When the first piezoelectric element 100A and the second piezoelectric element 100B generate multiple different unit signals from each other, a summed signal of multiple unit signals generated by the first piezoelectric element 100A may also be different from a summed signal of multiple unit signals generated by the second piezoelectric element 100B.

As described above, the N-hedral piezoelectric element 100 according to the present invention can have improved reliability and utilization due to the ability to generate multiple signals in response to one external force applied thereto.

Further, the N-hedral piezoelectric element 100 according to the present invention can have further improved reliability and utilization in piezoelectric products, such as sensors, actuators, transducers, and energy harvesters, due to the ability to output signals of various sizes and quantities in response to applied external force.

Next, a touchpad including a piezoelectric element according to the present invention and a method of operating the touchpad will be described.

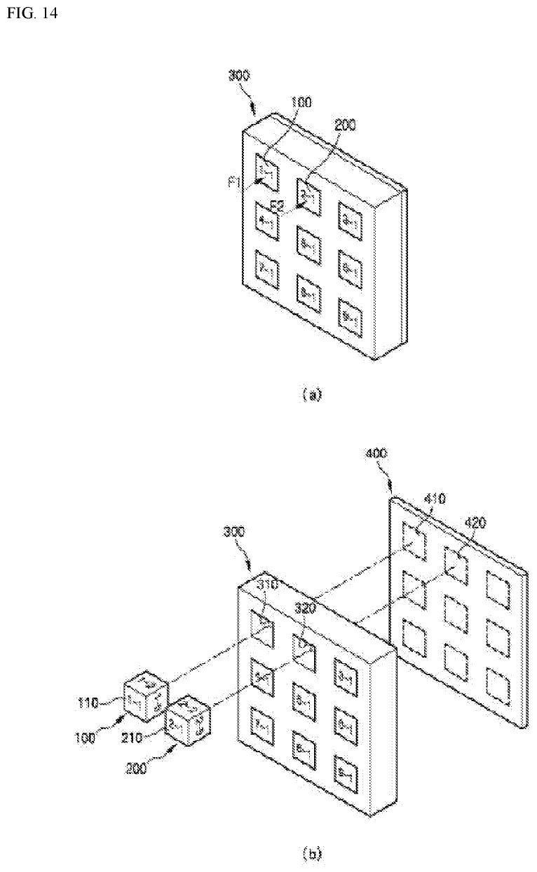

FIG. 14 is an exemplary view of a touchpad according to one embodiment of the present invention.

Referring to FIG. 14, a touchpad according to this embodiment may include a piezoelectric element, a pad body 300, and a signal processor 400.

The piezoelectric element may include multiple piezoelectric elements, including a first piezoelectric element 100, and may be the piezoelectric element 100 described above with reference to FIG. 1.

The first piezoelectric element 100 may have a shape of a polyhedron having n faces, that is, an N-hedron.

The first piezoelectric element 100 may include N polygonal unit piezoelectric films 110 forming N faces of the N-hedron.

In another embodiment, the first piezoelectric element 100 may have shape of a polyhedron having N faces (that is, an N-hedron) and may include one or more unit piezoelectric films forming one or more faces of the N-hedron, respectively, wherein the other faces of the N-hedron may be formed of a thin membrane or film. Accordingly, the first piezoelectric element 100 according to the other embodiment may generate one or more unit signals in response to pressure applied to one face of the N-hedron.

In the following, the present invention will be described with reference to an embodiment in which N faces of the N-hedron are formed of N polygonal unit piezoelectric films, respectively.

The first piezoelectric element 100 may be coupled to a first installation groove 310 of the pad body 300 with one of the N unit piezoelectric films 110 exposed externally. That is, a first external force F1 may be applied to the first piezoelectric element 100 through the one exposed unit piezoelectric film 110.

The first piezoelectric element 100 may have N first unit identification numbers corresponding to N faces of the N-hedron. For example, N faces of the N-hedral first piezoelectric element 100 may be assigned the first unit identification numbers from 1-1 to 1-N, respectively.

Each unit piezoelectric film 110 may generate a first unit signal in response to the first external force F1 applied to the first piezoelectric element 100. That is, the N-hedral first piezoelectric element 100 may generate N first unit signals in response to the first external force F1 applied thereto.

The N first unit signals generated by the first piezoelectric element 100 may be output as a first signal through a first signal processer 410. Here, the first signal may be one of the N first unit signals, or may be a sum of the N first unit signals.

In embodiments in which one or more of the N faces of the first piezoelectric element 100 are formed of a respective unit piezoelectric film and one or more first unit signals are generated by the one or more unit piezoelectric films, respectively, in response to the first external force applied to one of the N faces, the first signal may be one of the one or more first unit signals, or may be a sum of the one or more first unit signals. In addition, the same may be applied to a second piezoelectric element 200 described below.

The piezoelectric element may further include a second piezoelectric element 200.

The second piezoelectric element 200 may have substantially the same structure as the first piezoelectric element 100. That is, the second piezoelectric element 200 may have a shape of a polyhedron having N faces, that is, an N-hedron, and may include N polygonal unit piezoelectric films 210 forming the N faces of the N-hedron.

The second piezoelectric element 200 may be coupled to a second installation groove 320 of the pad body 300 with one of the N unit piezoelectric films 210 exposed externally. That is, a second external force F2 may be applied to the second piezoelectric element 200 through the one exposed unit piezoelectric film 210.

The second piezoelectric element 200 may have N second unit identification numbers corresponding to the N faces of the N-hedron. For example, the faces of the N-hedral second piezoelectric element 100 may be assigned the second unit identification numbers from 2-1 to 2-N, respectively.

Each of the unit piezoelectric films 210 may generate a second unit signal in response to the second external force F2 applied to the second piezoelectric element 200. That is, the N-hedral second piezoelectric element 100 may generate N second unit signals in response to the second external force F2 applied thereto.

The N second unit signals generated by the second piezoelectric element 200 may be output as a second signal through a second signal processer 420.

The pad body 300 may detachably support multiple piezoelectric elements and may include a first installation groove 310.

The first installation groove 310 may detachably support the first piezoelectric element 100 and may correspond in shape to the N-hedral first piezoelectric element 100. The first installation groove 310 may have an opening formed at one side thereof and allowing one of the multiple unit piezoelectric films 110 of the first piezoelectric element 100 to be exposed externally and an inner surface closely contacting an outer surface of the first piezoelectric element 100.

The pad body 300 may further include a second installation groove 320.

The second installation groove 320 may detachably support the second piezoelectric element 200 and may correspond in shape to the N-hedral second piezoelectric element 200. The second installation groove 320 may have the same structure as the first installation groove 310.

The pad body 300 may further include a cover.

The cover may be disposed on a surface of the pad body 300 having an installation groove formed thereon to protect a piezoelectric element inserted into and coupled to the installation groove from an outside environment. The cover may be formed of a transparent elastic material such that external force is transmitted to the piezoelectric element therethrough.

The signal processer 400 may be electrically connected to a piezoelectric element coupled to an installation groove and may include a first signal processer 410.

The first signal processer 410 may be electrically connected to the first piezoelectric element 100 coupled to the first installation groove 310 and may receive and process a first signal generated by the first piezoelectric element 100 in response to the first external force F1. Here, the first signal may be any of the N first unit signals generated by the N unit piezoelectric films constituting the first piezoelectric element 100. Alternatively, the first signal may be a sum of the N first unit signals generated by the N unit piezoelectric films constituting the first piezoelectric element 100.

The signal processer 400 may further include a second signal processer 420.

The second signal processer 420 may be electrically connected to the second piezoelectric element 200 coupled to the second installation groove 320 and may receive and process a second signal generated by the second piezoelectric element 200 in response to the second external force F1. Here, the second signal may be any of the N second unit signals generated by the N unit piezoelectric films constituting the second piezoelectric element 200. Alternatively, the second signal may be a sum of the N second unit signals generated by the N unit piezoelectric films constituting the second piezoelectric element 200.

The signal processer 400 may further include a signal determination unit.

The signal determination unit may compare and determine whether touch information applied to the multiple piezoelectric elements matches prestored reference touch information and may permit subsequent touchpad control procedures only when a determination is made that the touch information matches the reference touch information.

In the following, the process of processing the first signal and the second signal through the signal processer 400 will be described in detail with reference to an embodiment in which the touchpad includes the first piezoelectric element 100 and the second piezoelectric element 200 and the first external force F1 and the second external force F2 are applied to the first piezoelectric element 100 and the second piezoelectric element 200, respectively.

The signal determination unit of the signal processer 400 may include a reference signal storage unit.

The reference signal storage unit may prestore a reference input order of the first external force F1 and the second external force F2. Here, the reference input order may be preset by a user and may be an input order of the first external force F1 and the second external force F2 applied by the user. For example, the first external force F1 may be input before the second external force F2 is input, or the second external force F2 may be input before the first external force F1 is input.

In addition, the reference signal storage unit may prestore a first reference unit identification number and a second reference unit identification number. Here, the first reference unit identification number may be preset by a user and may be a first unit identification number subjected to the first external force F1, among N first unit identification numbers of the first piezoelectric element 100. In addition, the second reference unit identification number may be preset by a user and may be a second unit identification number subjected to the second external force F2, among N second unit identification numbers of the second piezoelectric element 200.

Further, the reference signal storage unit may prestore a first reference signal and a second reference signal. The first reference signal may be preset by a user and may be a first signal generated by the first piezoelectric element 100 in response to the first external force F1 applied by the user. The second reference signal may be preset by a user and may be a second signal generated by the second piezoelectric element 200 in response to the second external force F2 applied by the user. For example, the first reference signal and the second reference signal may be identical to each other, or may be different from each other.

Accordingly, the signal determination unit of the signal processer 400 may compare touch information applied to each of the first piezoelectric element 100 and the second piezoelectric element 200 with the prestored reference touch information to permit subsequent touchpad control procedures only when the touch information matches the reference touch information.

That is, the signal determination unit may be configured to permit subsequent touchpad control procedures only when an input order of the first external force F1 and the second external force F2 matches the preset reference input order, a first unit identification number subjected to the first external force F1, among the N first unit identification numbers, matches the preset first reference unit identification number, a second unit identification number subjected to the second external force F2, among the N second unit identification numbers, matches the preset second reference unit identification number, a magnitude of the first signal matches a magnitude of the preset first reference signal, and a magnitude of the second signal matches a magnitude of the preset second reference signal.

For example, when the touchpad according to this embodiment is used as a door lock, the door lock may be unlocked only when touch information applied to the first piezoelectric element 100 and the second piezoelectric element 200 by a user perfectly matches the preset reference touch information, as described above.

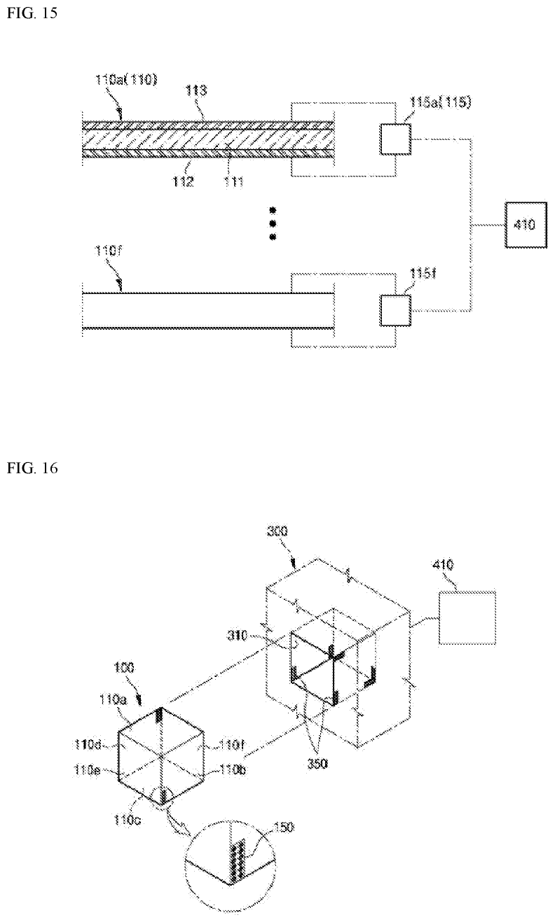

FIG. 15 is an exemplary partial sectional view of a unit piezoelectric film according to another embodiment of the present invention.

Referring first to FIG. 3, a first piezoelectric element 100 having a hexahedral shape may include six unit piezoelectric films 110a, 110b, 110c, 110d, 110e, 110f.

Each unit piezoelectric film 110 may be provided in the form of a thin membrane or film and may include a piezoelectric material layer 111, a first electrode 112 disposed on one surface of the piezoelectric material layer 111, and a second electrode 113 disposed on the other surface of the piezoelectric material layer 111 and having an opposite polarity to the first electrode 112.

That is, the unit piezoelectric film 110 may be fabricated by sequentially stacking the first electrode 112, the piezoelectric material layer 111, and the second electrode 113. Although the unit piezoelectric film 110 is shown as including a single piezoelectric material layer 111, it should be understood that the present invention is not limited thereto and the unit piezoelectric film 110 may include a stack of multiple piezoelectric material layers 111. The piezoelectric material layer 111 may include PVDF, PZT, BaTiO₃, LiNbO₃, quartz, and the like.

When external pressure is applied to the unit piezoelectric film 110 in a certain direction, a positive (+) charge is induced on the first electrode 112 and a negative (−) charge is induced on the second electrode 113 in response to stress (resistance force) generated in the unit piezoelectric film 110, causing generation of voltage between the first electrode 112 and the second electrode 113.

The unit piezoelectric film 110 may be electrically connected to a unit signal measurement unit 115. The unit signal measurement unit 115 may measure an electrical signal as voltage generated between the first electrode 112 and the second electrode 113. The unit signal measurement unit 115 may measure a first unit signal generated by the unit piezoelectric film 110 and there may be N unit signal measurement units 115a to 115f corresponding to N unit piezoelectric films 110a to 110f. Accordingly, the first piezoelectric element 100 having a shape of an N-hedron may simultaneously generate N first unit signals in response to one external force F1.

The unit signal measurement unit 115 may be electrically connected to a first signal processer 410. That is, N first unit signals measured by the N unit signal measurement units 115a to 115f are transmitted to the first signal processer 410. The first signal processer 410 may individually output the N first unit signals generated by the N-hedral first piezoelectric element 100, may output only one of the N first unit signals, or may output a first signal produced by summing the N first unit signals, as needed.

Next, operation of a piezoelectric element for the touchpad according to the present invention will be described.

Referring to FIG. 3 and FIG. 4, a hexahedral first piezoelectric element 100 may include six unit piezoelectric films 110a, 110b, 110c, 110d, 110e, 110f.

When a first external force F1 is applied to one face of the hexahedral first piezoelectric element 100, that is, one unit piezoelectric film 110a, the hexahedral first piezoelectric element 100 may generate six first unit signals, which, in turn, may be summed into a first signal.

Here, each of the six unit signals may depend on stress generated in a corresponding one of the six unit piezoelectric films 110a, 110b, 110c, 110d, 110e, 110f in response to the first external force F1 and a poling direction of a corresponding one of the unit piezoelectric films 110a, 110b, 110c, 110d, 110e, 110f.

As a result, the first signal produced by summing the six first unit signals may vary depending on which of the six unit piezoelectric films 110a, 110b, 110c, 110d, 110e, 110f is subjected to the first external force F1. That is, the first signal may vary depending on which of the six first unit identification numbers of the hexahedral first piezoelectric element 100 is subjected to the first external force F1.

Referring further to FIG. 4, the first piezoelectric element 100 may include a first unit piezoelectric film 110a and a second unit piezoelectric film 110b and the first external force F1 may be applied in a direction perpendicular to a plane of the first unit piezoelectric film 110a.

The first unit piezoelectric film 110a may be disposed perpendicular to the first external force F1. The first unit piezoelectric film 110a may have a first poling direction Pa with respect to the first external force F1 and a first stress fa may be generated in the first unit piezoelectric film 110a against the first external force F1. For example, the first stress may be compressive or tensile stress. Accordingly, the first unit piezoelectric film 110a having the first poling direction Pa may generate a 1-1 unit signal sa corresponding to the first stress fa.

For a hexahedral piezoelectric element 100, the first unit piezoelectric film 110a subjected to the first external force F1 may generate the same unit signal corresponding to the first stress fa, regardless of the first poling direction Pa thereof.

The second unit piezoelectric film 110b may be joined edge-to-edge with the first unit piezoelectric film 110a to be disposed at a predetermined angle of inclination with respect to the first external force F1. The second unit piezoelectric film 110b may have a second poling direction Pb with respect to the first external force F1 and a second stress fb may be generated in the second unit piezoelectric film 110b against the first external force F1. The second poling direction Pb may be different from the first poling direction Pa, and the magnitude of the second stress fb may be different from that of the first stress fa. For example, the second stress fb may be bending stress. Accordingly, the second unit piezoelectric film 110b having the second poling direction Pb may generate a 1-2 unit signal sb corresponding to the second stress fb.

The first piezoelectric element 100 may further include a third unit piezoelectric film 110c and a fourth unit piezoelectric film 110d.

The third unit piezoelectric film 110c may be joined edge-to-edge with the second unit piezoelectric film 110b to be disposed perpendicular to the first external force F1. The third unit piezoelectric film 110c may have a third poling direction Pc with respect to the first external force (F1) and a third stress fc may be generated in the third unit piezoelectric film 110c against the first external force F1. The third poling direction Pc may be different from the first poling direction Pa and the second poling direction Pb, and the magnitude of the third stress fc may be different from those of the first stress fa and the second stress fb. For example, the third stress fc may be compressive or tensile stress. Accordingly, the third unit piezoelectric film 110c having the third poling direction Pc may generate a 1-3 signal sc corresponding to the third stress fc.

For a hexahedral piezoelectric element 100, the 1-3 unit signal sc may be identical to the 1-1 unit signal sa. That is, the third unit piezoelectric film 110c disposed opposite the first unit piezoelectric film 110a subjected to the first external force F1 may generate the same unit signal as the first unit piezoelectric film 110a, regardless of the third poling direction Pc thereof.

The fourth unit piezoelectric film 110d may be joined edge-to-edge with the first unit piezoelectric film 110a to be disposed at a predetermined angle of inclination with respect to the first external force F1. The fourth unit piezoelectric film 110d may have a fourth poling direction Pd with respect to the first external force F1 and a fourth stress fd may be generated in the fourth unit piezoelectric film 110d against the first external force F1. The fourth poling direction Pd may be different from the first poling direction Pa, the second poling direction Pb, and the third poling direction Pc, and the magnitude of the fourth stress fd may be different from those of the first stress fa, the second stress fb, and the third stress fc. For example, the fourth stress fd may be bending stress. Accordingly, the fourth unit piezoelectric film 110d having the fourth poling direction Pd may generate a 1-4 unit signal sd corresponding to the fourth stress fd.

Although not shown, a hexahedral piezoelectric element 100 may further include a fifth unit piezoelectric film and a sixth unit piezoelectric film.

The fifth unit piezoelectric film may be joined edge-to-edge with the first unit piezoelectric film 110a, may have a fifth poling direction with respect to the first external force F1, and may generate a 1-5 unit signal upon generation of a fifth stress against the first external force F1. The sixth unit piezoelectric film may be joined edge-to-edge with the first unit piezoelectric film 110a, may have a sixth poling direction with respect to the first external force F1, and may generate a 1-6 unit signal upon generation of a sixth stress against the first external force F1.

Although FIG. 5 shows that the poling direction P of the unit piezoelectric film 110 is oriented upward, downward, leftward, or rightward, it should be understood that the present invention is not limited thereto and each unit piezoelectric film 110 may have a poling direction P oriented at an oblique angle.

That is, each unit piezoelectric film 110 may have a poling direction P oriented right upward, left downward, left upward, or right downward. Accordingly, the multiple unit piezoelectric films 110 may generate multiple different unit signals, respectively, depending on the obliquely oriented poling directions P thereof.

When each unit piezoelectric film 110 has an obliquely oriented poling direction P, the poling directions P of the respective unit piezoelectric films 110 may have different slopes.

As described above, for a hexahedral piezoelectric element 100, the first unit piezoelectric film 110a subjected to the first external force F1 and the third unit piezoelectric film 110c disposed opposite the first unit piezoelectric film 110a may generate the same unit signal regardless of the poling directions P thereof, and the other unit piezoelectric films 110b, 110d, 110e, 110f joined edge-to-edge with the first unit piezoelectric film 110a and the third unit piezoelectric film 110c and forming four side surfaces of the hexahedral piezoelectric element 100 may generate different unit signals depending on the poling directions P thereof.

Upon receiving the 1-1 unit signal sa, the 1-2 unit signal sb, the 1-3 unit signal sc, the 1-4 unit signal sd, the 1-5 unit signal, and the 1-6 unit signal, the first signal processer 410 may output only one of the 1-1 unit signal sa, the 1-2 unit signal sb, the 1-3 unit signal sc, the 1-4 unit signal sd, the 1-5 unit signal, and the 1-6 unit signal, or may output a first signal produced by summing the 1-1 unit signal sa, the 1-2 unit signal sb, the 1-3 unit signal sc, the 1-4 unit signal sd, the 1-5 unit signal, and the 1-6 unit signal.

When the unit piezoelectric film subjected to the first external force F1 (that is, the unit piezoelectric film corresponding to the first reference unit identification number) is changed from one of the first to sixth unit piezoelectric films 110a to 110f to another by changing a position of the first piezoelectric element 100 on the first installation groove 310, stress generated in each of the first to sixth unit piezoelectric films 110a to 110f and the poling direction of each of the first to sixth unit piezoelectric films 110a to 110f are changed, resulting in change of the first signal produced by summing the 1-1 to 1-6 unit signals.

Needless to say, the 1-1 to 1-6 unit signals may vary in magnitude depending on the magnitude of the first external force F1 and thus the first signal produced by summing the 1-1 to 1-6 unit signals may also vary in magnitude depending on the magnitude of the first external force F1.

In addition, stress generated in each unit piezoelectric film may vary in magnitude depending on the type of N-hedron. Further, stress generated in each unit piezoelectric film may vary in magnitude depending on various parameters of the piezoelectric material layer 111 of a corresponding unit piezoelectric film, such as the type of material, thickness, width, length, elastic modulus, dielectric constant, and static displacement rate.

N unit piezoelectric films 110 may be poled in respective predetermined directions P through a piezoelectric element manufacturing process. For example, by fabricating a mother piezoelectric film sheet 10 having a predetermined poling direction P (see FIG. 8), cutting the fabricated mother piezoelectric film sheet 10 into a piezoelectric film net 11 for an N-hedron (see FIG. 9), and processing the formed piezoelectric film net 11 into the N-hedron, N unit piezoelectric films 110 forming N faces of the N-hedron may have different poling directions P (see FIG. 10).

FIG. 16 is an exemplary view illustrating coupling between a piezoelectric element and a pad body according to another embodiment of the present invention.

Referring to FIG. 16, a first piezoelectric element 100 according to this embodiment may further include an integrated electrode unit 150.

For example, there may be at least two integrated electrode units 150 formed at one side of an outer surface of the first piezoelectric element 100 facing a first installation groove 310 and electrically connected to a first electrode 112 (see FIG. 15) and a second electrode 113 (see FIG. 15) of each of N unit piezoelectric films 110.

A pad body 300 according to this embodiment may further include an electrode connection portion 350.

The electrode connection portion 350 may be formed on each inner surface of the first installation groove 310, excluding an opening of the first installation groove 310, and may be electrically connected to the integrated electrode unit 150 regardless of a position of the first piezoelectric element 100 on the first installation groove 310.

Upon coupling the first piezoelectric element 100 to the first installation groove 310, the integrated electrode unit 150 is electrically connected to the electrode connection portion 350, whereby electrical connection between the first piezoelectric element 100 and a first signal processer 410 is established.

Accordingly, the signal processor 400 may determine a position of the first piezoelectric element 100 on the first installation groove 310 based on information about connection between the integrated electrode unit 150 and the electrode connection portion 350. That is, the signal processor 400 may determine a position of a unit piezoelectric film 110 exposed outside the first installation groove 310 to be directly subjected to the first external force F1.

The signal processer 400 may output a single first signal produced by summing multiple first unit signals generated by the multiple unit piezoelectric films 101a, 101b, 101c, 101d, 101e, 101f, respectively.

Next, a touchpad operation method according to the present invention will be described.

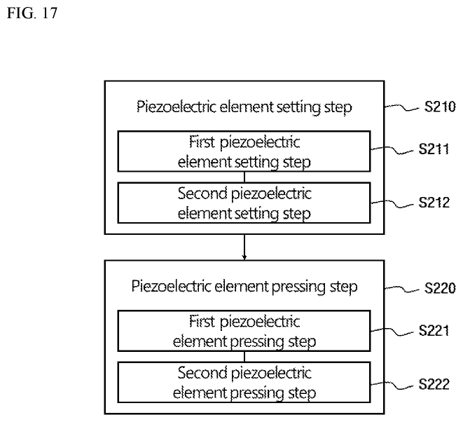

FIG. 17 is a flow diagram of a touchpad operation method according to one embodiment of the present invention.

Referring to FIG. 1 and FIG. 17, the touchpad operation method according to this embodiment provides a process for operating the touchpad described above, and may include a piezoelectric element setting step S210 and a piezoelectric element pressing step S220.

The piezoelectric element setting step S210 may be a step in which a position of an N-hedral piezoelectric element on an installation groove of the pad body 300 is set such that a predetermined face of the piezoelectric element is exposed externally.

The piezoelectric element setting step S210 may include a first piezoelectric element setting step S211 and a second piezoelectric element setting step S212.

The first piezoelectric element setting step S211 may be a step in which a position of an N-hedral first piezoelectric element 100 on the first installation groove 310 of the pad body 300 such that a predetermined face of the first piezoelectric element 100 is exposed externally.

That is, the position of the first piezoelectric element 100 on the first installation groove 310 is set such that, among N first unit identification numbers of the first piezoelectric element 100, a first unit identification number that matches a preset first reference unit identification number is exposed outside the pad body 300 to be subjected to the first external force F1.

The second piezoelectric element setting step S212 may be a step in which a position of an N-hedral second piezoelectric element 200 on the second installation groove 320 of the pad body 300 is set such that a predetermined face of the second piezoelectric element 200 is exposed externally.

That is, the position of the second piezoelectric element 200 on the second installation groove 330 is set such that, among N second unit identification numbers of the second piezoelectric element 200, a second unit identification number that matches a preset second reference unit identification number is exposed outside the pad body 300 to be subjected to the second external force F2.

After position setting of the piezoelectric element is completed, external force is applied to the piezoelectric element.

The piezoelectric element pressing step S220 may be a step in which the piezoelectric element is pressed in accordance with preset reference touch information.

The piezoelectric element pressing step S220 may include a first piezoelectric element pressing step S221 and a second piezoelectric element pressing step S222.

Specifically, first, an input order of the first external force F1 applied to the first piezoelectric element 100 and the second external force F2 applied to the second piezoelectric element 200 is determined in accordance with a preset reference input order.

In addition, a magnitude of the first external force F1 to be applied to the first piezoelectric element 100 is determined in accordance with a magnitude of a preset first reference signal and a magnitude of the second external force F2 to be applied to the second piezoelectric element 200 is determined in accordance with a magnitude of a preset second reference signal.

Then, the first piezoelectric element 100 and the second piezoelectric element 200 are pressed in accordance with preset reference touch information.

In this way, it is possible to ensure that subsequent touchpad control procedures are only permitted when touch information applied to the first piezoelectric element 100 and the second piezoelectric element 200 matches the preset reference touch information.

As described above, the touchpad including an N-hedral piezoelectric element according to the present invention has improved operational reliability and security level due to the ability to output various signals depending on which face of the piezoelectric element is subjected to external force.

In addition, the touchpad including an N-hedral piezoelectric element according to the present invention has further improved operational reliability and security level due to the ability to output various signals depending on the magnitude of external force.

Further, the touchpad including the N-hedral piezoelectric element according to the present invention is easy to manufacture since a signal generated by each face of the piezoelectric element can be varied through change of a net pattern for an N-hedron.

Furthermore, the touchpad including the N-hedral piezoelectric element according to the present invention can be used in a wide range of applications due to the ability to set and output signals of various sizes and quantities in response to external force.

Although exemplary embodiments have been described with reference to the accompanying drawings, it should be understood that various modifications, changes, alterations, and equivalent embodiments can be made by those skilled in the art without departing from the spirit and scope of the invention.

### LIST OF REFERENCE NUMERALS

100: Piezoelectric element, first piezoelectric element
110: Unit piezoelectric film
200: Second piezoelectric element
300: Pad body
400: Signal processer

1. A piezoelectric element having a shape of an N-hedron and comprising N unit piezoelectric films having a shape of a polygon and forming N faces of the N-hedron,
wherein N unit signals are generated by the N unit piezoelectric films in response to one external force applied to one face of the N-hedron.

2. The piezoelectric element according to claim 1, wherein each of the N unit signals depends on stress generated in a corresponding one of the N unit piezoelectric films in response to the one external force and a poling direction of a corresponding one of the N unit piezoelectric films.

3. The piezoelectric element according to claim 1, wherein the N unit piezoelectric films comprise:
a first unit piezoelectric film in which a first stress is generated against the one external force; and
a second unit piezoelectric film in which a second stress is generated against the one external force.

4. The piezoelectric element according to claim 3, wherein the first unit piezoelectric film has a first poling direction with respect to the one external force and the second unit piezoelectric film has a second poling direction different from the first poling direction with respect to the one external force.

5. The piezoelectric element according to claim 4, wherein the first unit piezoelectric film generates a first unit signal corresponding to the first stress and the first poling direction, and the second unit piezoelectric film generates a second unit signal corresponding to the second stress and the second poling direction.

6. The piezoelectric element according to claim 1, wherein the N unit piezoelectric films are formed by cutting a mother piezoelectric film sheet having a predetermined poling direction.

7. The piezoelectric element according to claim 1, wherein the N-hedron is a regular N-hedron and the polygon is a regular polygon.

8. A piezoelectric element having a shape of an N-hedron and comprising one or more unit piezoelectric films forming one or more faces of the N-hedron, respectively,
wherein one or more unit signals are generated by the one or more unit piezoelectric films, respectively, in response to one external force applied to one face of the N-hedron.

9. A touchpad comprising:
a first piezoelectric element having a shape of an N-hedron;
a pad body having a first installation groove detachably supporting the first piezoelectric element; and
a signal processer receiving and processing a first signal generated by the first piezoelectric element in response to a first external force.

10. The touchpad according to claim 9, further comprising:
a second piezoelectric element having a shape of an N-hedron,
wherein the pad body further has a second installation groove detachably supporting the second piezoelectric element, and
the signal processer further receives and processes a second signal generated by the second piezoelectric element in response to a second external force.

11. The touchpad according to claim 9, wherein the first signal generated by the first piezoelectric element varies depending on which face of the N-hedron is subjected to the first external force.

12. The touchpad according to claim 9, wherein the first signal generated by the first piezoelectric element varies depending on a magnitude of the first external force.

13. The touchpad according to claim 10, wherein the first piezoelectric element comprises N first unit identification numbers corresponding to N faces thereof and the second piezoelectric element comprises N second unit identification numbers corresponding to N faces thereof.

14. The touchpad according to claim 13, wherein the signal processer compares and determines:
whether an input order of the first external force and the second external force matches a preset reference input order;
whether, among the N first unit identification numbers, a first unit identification number subjected to the first external force matches a preset first reference unit identification number;
whether, among the N second unit identification numbers, a second unit identification number subjected to the second external force matches a preset second reference unit identification number;
whether a magnitude of the first signal matches a magnitude of a preset first reference signal; and
whether a magnitude of the second signal matches a magnitude of a preset second reference signal.

15. The touchpad according to claim 9, wherein:
the first piezoelectric element comprises N unit piezoelectric films forming N faces of the N-hedron;
N first unit signals are generated by the N unit piezoelectric films in response to the first external force applied to one of the N unit piezoelectric films; and
the first signal is one of the N first unit signals or a sum of the N first unit signals.

16. The touchpad according to claim 14, wherein:
each of the N unit piezoelectric films comprises a first electrode and a second electrode; and
the first piezoelectric element comprises at least two integrated electrode units formed at one side of an outer surface thereof facing the first installation groove and electrically connected to the N first electrodes and the N second electrodes.

17. The touchpad according to claim 16, wherein the pad body comprises an electrode connection portion formed on each inner surface of the first installation groove, excluding an opening of the first installation groove, to be electrically connected to the integrated electrode units, regardless of a position of the first piezoelectric element on the first installation groove.

18. The touchpad according to claim 9, wherein:
the first piezoelectric element comprises one or more unit piezoelectric films forming one or more faces of the N-hedron, respectively;
one or more first unit signals are generated by the one or more unit piezoelectric films, respectively, in response to the first external force applied to one face of the N-hedron; and
the first signal is one of the one or more first unit signals or a sum of the one or more first unit signals.
